(19) United States
(12) Patent Application Publication
(10) Pub. No.: US 2002/0098663 A1
(43) Pub. Date: Jul. 25, 2002

(54) Manufacturing method of a semiconductor device

(75) Inventors: Koji Miyamoto, Yokohama-shi (JP); Kohtaro Inoue, Kawasaki-shi (JP)

Correspondence Address: FINNEGAN, HENDERSON, FARABOW, GARRETT &, DUNNER LLP, 1300 I STREET, NW, WASHINGTON, DC, 20005, US

(73) Assignee: Kabushiki Kaisha Toshiba

(21) Appl. No.: 10/106,063

(22) Filed: Mar. 27, 2002

Related U.S. Application Data
(62) Division of application No. 09/527,596, filed on Mar. 17, 2000.

(30) Foreign Application Priority Data
Mar. 19, 1999 (JP) 11-076057
Mar. 3, 2000 (JP) 2000-059123

(51) Int. Cl. H01L 21/76

(52) U.S. Cl. 438/431

(57) ABSTRACT

In the formation of a P-type rediffusion region adjacent to a source drain region in an N well, boron fluoride is implanted without a P well covered with a mask. And in the formation of an N-type rediffusion region adjacent to a source drain region in a P well, phosphorus is implanted with an N well covered with a mask. The dose of boron fluoride implanted without a mask is smaller than the dose of phosphorus.

### CROSS-REFERENCE TO RELATED APPLICATIONS

This application is based upon and claims the benefit of priority from the prior Japanese Patent Application No. 11-076057, filed Mar. 19, 1999; and No. 2000-059123, filed Mar. 3, 2000, the entire contents of which are incorporated herein by reference.

### BACKGROUND OF THE INVENTION

The present invention relates to a method of manufacturing a semiconductor device used in a contact process, especially in a rediffusion ion implantation process.

In recent years, the diameter of a contact has been reduced as a semiconductor device has been made smaller, and for the sake of design, a mounted contact, a contact part of which is mounted on a field insulation film (oxide layer), has come to be adopted. In the case of this contact, however, because part of a contact is mounted on a field insulation film, the contact area between the contact and the diffusion layer reduces, and the resistance of the contact increases and a junction leak arises as a result. In order to lower the contact resistance, after the contact is opened, it becomes necessary to implant ions for rediffusion to form a rediffusion layer adjacent to a diffusion layer and in touch with the contact. N⁺-type and P⁺-type rediffusion regions are explained below.

As shown in FIG. 30, in a semiconductor substrate 11, an N well 16 and a P well 17 are formed, and on the surface of the N well 16 and the P well 17, a plurality of field insulation films 24 are formed. On the N well 16 and the P well 17, gate electrodes 31a are formed through a gate insulation film (not shown), and on the field insulation films 24, wiring, passing gate electrodes 31b, for example, are formed. In the N well 16 which is on both sides of the gate electrodes 31a, a P-type source drain region 36a is formed, while in the P well 17 which is on both sides of the gate electrodes 31a, an N-type source drain region 39a is formed. On the entire surface of the semiconductor substrate 11, an interlayer insulation film 40 which is a CVDSiO₂ film containing phosphorus or boron is formed, and the surface of the interlayer insulation film 40 is flattened by the CMP (Chemical Mechanical Polish) method. The interlayer insulation film 40 has the P-type source drain region 36a, the N-type source drain region 39a, and a plurality of contact holes 42 which expose the surface of the passing gate electrodes 31b.

Thereafter, a patterned resist 53 is formed, and boron fluoride (BF₂), for instance, is implanted into the N well 16 from the contact holes 42. By this procedure, a P-type rediffusion region 43 is formed on the surface of the N well 16 at the bottom of the contact holes 42. Then the resist 53 is removed.

Next, as shown in FIG. 31, a resist 54 is formed and patterned. The patterned resist 54 is used to implant phosphorus (P), for example, into the P well 17 from the contact holes 42. By this procedure, an N-type rediffusion region 45 is formed on the surface of the P well 17 at the bottom of the contact holes 42.

As was described above, the P-type rediffusion region 43 and the N-type rediffusion region 45 were formed at the bottom of the contact holes 42; the contacting area with the contact was thus increased, and the resistance of the contact was reduced as a result.

In the above-mentioned manufacturing method in prior art, however, when the P-type rediffusion region 43 is formed, the P well 17 is covered with a mask, whereas when the N-type rediffusion region 45 is formed, the N well 16 is covered with a mask. That is to say, there needs to be a process according to which the resists 53, 54 functioning as mask are formed and removed. Therefore, there arises a problem in which the process of implantation ions takes a long time. In addition, dust tends to rise as the resists 53, 54 are formed and removed, thereby lowering yield.

### BRIEF SUMMARY OF THE INVENTION

An object of the present invention which was made to solve the above-mentioned problems is to provide a manufacturing method of a semiconductor device which simplifies the process of implantation ions.

In order to attain the above object, the present invention has the following means.

A first method of manufacturing a semiconductor device according to the present invention is designed to manufacture a semiconductor device having a first electrically conductive first well region and a second electrically conductive second well region in the surface region of a semiconductor substrate; a first transistor and a second transistor having a second electrically conductive first diffusion layer and a first electrically conductive second diffusion layer in the first and second well regions respectively; and an insulation film having contact holes which expose at least the first and second diffusion layers of the first and second transistors; and comprising a process of implantation first ions on the entire surface of the semiconductor substrate from the contact holes, and thereby forming a second electrically conductive first rediffusion region adjacent to the first diffusion layer in the first well region; a process of forming a mask covering the first well region of the semiconductor substrate; and a process of implantation second ions in the second well region from the contact holes using the mask, and thereby forming the first electrically conductive second rediffusion region adjacent to the second diffusion layer in the second well region; wherein the dose in implantation the first ions in the process of forming the first rediffusion region is smaller than the dose in implantation the second ions in the process of forming the second rediffusion layer.

In the first method, as a condition of implantation the first ions in forming the first rediffusion region, it is desirable that the acceleration voltage be from 30 to 50 keV and the dose be from 6.0×10¹⁴ to 1.5×10¹⁵ cm⁻², while as a condition of implantation the second ions in forming the second rediffusion region, it is desirable that the acceleration voltage be 60 keV and the dose be 3.0×10¹⁵ cm⁻².

A second manufacturing method of a semiconductor device according to the present invention is designed to manufacture a semiconductor device having a first electrically conductive first well region and a second electrically conductive second well region in the surface region of a semiconductor substrate; a first transistor and a second transistor having a second electrically conductive first diffusion layer and a first electrically conductive second diffusion layer in the first and second well regions respectively; and an insulation film having contact holes which expose at least the first and second diffusion layers of the first and second transistors; and comprising a process of forming a mask covering the second well region of the semiconductor substrate; a process of implantation first ions in the first well region from the contact holes using the mask, and thereby forming the second electrically conductive first rediffusion region adjacent to the first diffusion layer in the first well region; a process of removing the mask; and a process of implantation second ions on the entire surface of the semiconductor substrate from the contact holes, and thereby forming the first electrically conductive second rediffusion region adjacent to the second diffusion layer in the second well region; wherein the dose in implantation the second ions in the process of forming the second rediffusion layer is smaller than the dose in implantation the first ions in the process of forming the firs rediffusion region.

In the second method, as a condition of implantation the second ions in forming the second rediffusion region, it is desirable that the acceleration voltage be from 30 to 50 keV and the dose be from 6.0×10¹⁴ to 1.5×10¹⁵ cm⁻², while as a condition of implantation the first ions in forming the first rediffusion region, it is desirable that the acceleration voltage be 60 keV and the dose be 3.0×10¹⁵ cm⁻².

As was described above, according to the present invention, it is possible to provide a manufacturing method of a semiconductor device which simplifies the process of implantation ions.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a cross-sectional view of the manufacturing process of a semiconductor device according to a first embodiment of the present invention;

FIG. 2 is a cross-sectional view following FIG. 1 of the manufacturing process of a semiconductor device according to a first embodiment of the present invention;

FIG. 3 is a cross-sectional view following FIG. 2 of the manufacturing process of a semiconductor device according to a first embodiment of the present invention;

FIG. 4 is a cross-sectional view following FIG. 3 of the manufacturing process of a semiconductor device according to a first embodiment of the present invention;

FIG. 5 is a cross-sectional view following FIG. 4 of the manufacturing process of a semiconductor device according to a first embodiment of the present invention;

FIG. 6 is a cross-sectional view following FIG. 5 of the manufacturing process of a semiconductor device according to a first embodiment of the present invention;

FIG. 7 is a cross-sectional view following FIG. 6 of the manufacturing process of a semiconductor device according to a first embodiment of the present invention;

FIG. 8 is a cross-sectional view following FIG. 7 of the manufacturing process of a semiconductor device according to a first embodiment of the present invention;

FIG. 9 is a cross-sectional view following FIG. 8 of the manufacturing process of a semiconductor device according to a first embodiment of the present invention;

FIG. 10 is a cross-sectional view following FIG. 9 of the manufacturing process of a semiconductor device according to a first embodiment of the present invention;

FIG. 11 is a cross-sectional view following FIG. 10 of the manufacturing process of a semiconductor device according to a first embodiment of the present invention;

FIG. 12 is a cross-sectional view following FIG. 11 of the manufacturing process of a semiconductor device according to a first embodiment of the present invention;

FIG. 13 is a cross-sectional view following FIG. 12 of the manufacturing process of a semiconductor device according to a first embodiment of the present invention;

FIG. 14 is a cross-sectional view following FIG. 13 of the manufacturing process of a semiconductor device according to a first embodiment of the present invention;

FIG. 15 is a cross-sectional view following FIG. 14 of the manufacturing process of a semiconductor device according to a first embodiment of the present invention;

FIG. 16 is a cross-sectional view following FIG. 15 of the manufacturing process of a semiconductor device according to a first embodiment of the present invention;

FIG. 17 is a cross-sectional view following FIG. 16 of the manufacturing process of a semiconductor device according to a first embodiment of the present invention;

FIG. 18 is a cross-sectional view following FIG. 17 of the manufacturing process of a semiconductor device according to a first embodiment of the present invention;

FIG. 19 is a cross-sectional view following FIG. 18 of the manufacturing process of a semiconductor device according to a first embodiment of the present invention;

FIG. 20 is a cross-sectional view following FIG. 19 of the manufacturing process of a semiconductor device according to a first embodiment of the present invention;

FIG. 21 is a cross-sectional view following FIG. 20 of the manufacturing process of a semiconductor device according to a first embodiment of the present invention;

FIG. 22 is a cross-sectional view following FIG. 21 of the manufacturing process of a semiconductor device according to a first embodiment of the present invention;

FIG. 23 is a cross-sectional view following FIG. 16 of the manufacturing process of a semiconductor device according to a second embodiment of the present invention;

FIG. 24 is a cross-sectional view following FIG. 23 of the manufacturing process of a semiconductor device according to a second embodiment of the present invention;

FIG. 25 is a cross-sectional view following FIG. 16 of the manufacturing process of a semiconductor device according to a third embodiment of the present invention;

FIG. 26 is a cross-sectional view following FIG. 25 of the manufacturing process of a semiconductor device according to a third embodiment of the present invention;

FIG. 27 is a cross-sectional view following FIG. 25 of the manufacturing process of a semiconductor device according to a third embodiment of the present invention;

FIG. 28 is a diagram showing the condition of the dose and the acceleration voltage when a rediffusion region is formed;

FIG. 29 is a schematic drawing comparing a manufacturing process in prior art and the manufacturing process according to the present invention;

FIG. 30 is a cross-sectional view of the manufacturing process of a semiconductor device in prior art; and

FIG. 31 is a cross-sectional view following FIG. 30 of the manufacturing process of a semiconductor device in prior art.

### DETAILED DESCRIPTION OF THE INVENTION

Embodiments of the present invention will now be described with reference to the accompanying drawings.

[First Example]

A first embodiment is characterized in that a semiconductor device has a laminated structure, and ions are implanted without a mask when a P-type rediffusion region 43 is formed.

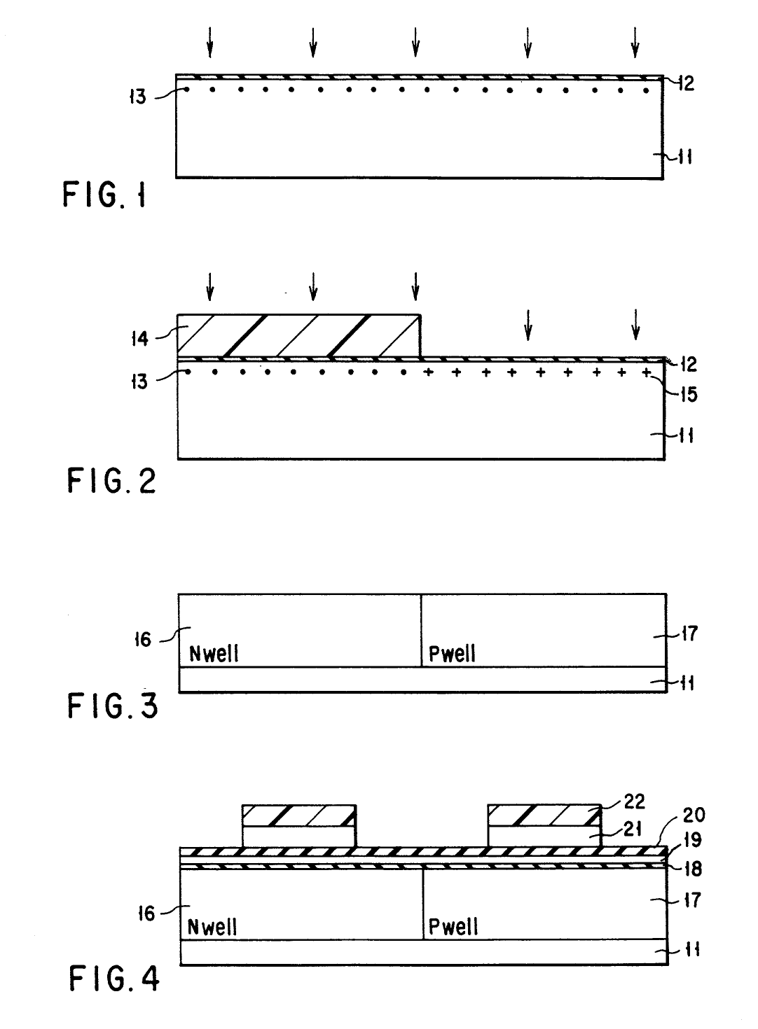

As shown in FIG. 1, a silicon oxide film 12 is formed on a P-type semiconductor substrate 11, for instance. Ions are then implanted and thus an N-type impurity region 13 is formed on the surface of the semiconductor substrate 11. The condition of the ion implantation is that when phosphorus (P), for example, is used as an ion, the acceleration voltage be 160 keV and the dose be 5.6×10¹² cm⁻².

As shown in FIG. 2, a resist 14 is formed on the silicon oxide film 12 and is patterned. Ions are implanted with the patterned resist 14 as a mask, and thus a P-type impurity region 15 is formed on the surface of the semiconductor substrate 11. The condition of the ion implantation is that when boron (B), for example, is used as an ion, the acceleration voltage be 160 keV and the dose be 1.55×10¹³ cm⁻². The resist 14 is removed thereafter.

As shown in FIG. 3, impurity in the N-type impurity region 13 and the P-type impurity region 15 is diffused, and thus an N well 16 and a P well 17 are formed respectively on the semiconductor substrate 11. Then the silicon oxide film 12 is removed.

As shown in FIG. 4, a silicon oxide film 18 is formed on the semiconductor substrate 11, and then a first polysilicon film 19 is formed on the silicon oxide film 18. On the first polysilicon film 19 a silicon nitride film 20 is formed, and then on the silicon nitride film 20 a second polysilicon film 21 is formed. On the second polysilicon film 21 a resist 22 is formed and patterned. With the patterned resist 22 as a mask, the second polysilicon film 21 is removed by the RIE (Reactive Ion Etching), for instance. Then the resist 22 is removed.

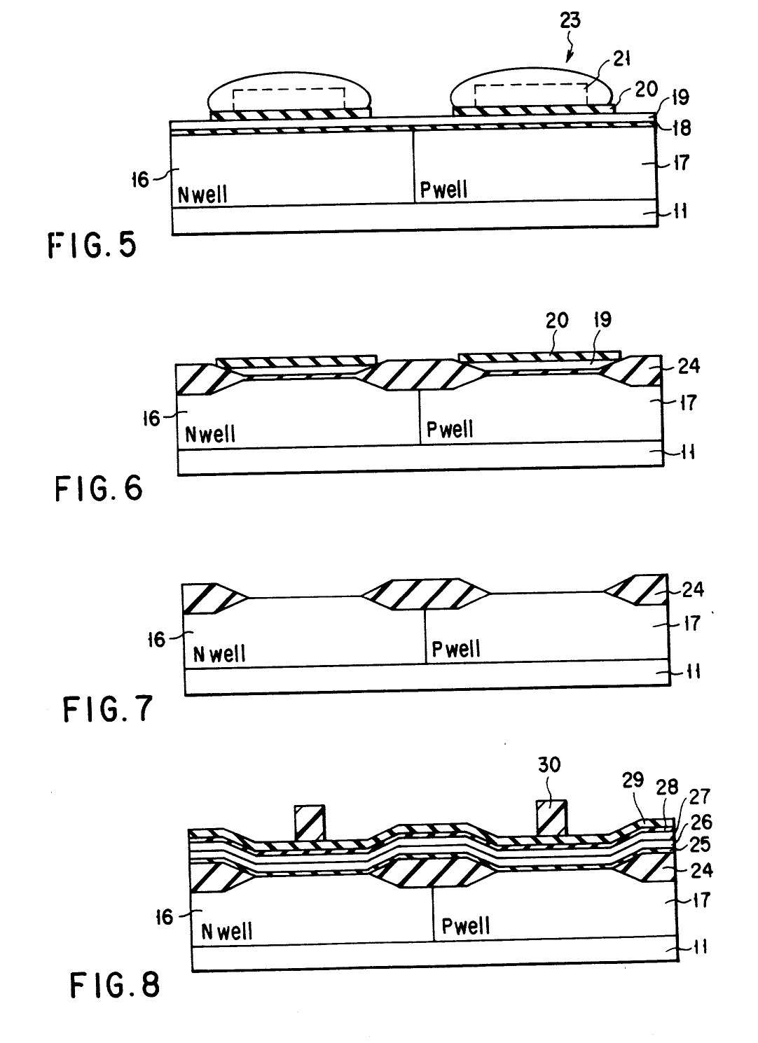

As shown in FIG. 5, the second polysilicon film 21 is oxidized and thus an oxidized polysilicon film 23 is formed. With the oxidized polysilicon film 23 as a mask, the silicon nitride film 20 is removed by the RIE, for example. Then the oxidized polysilicon film 23 is removed by the wet etching and so on, for instance.

As shown in FIG. 6, a field insulation film 24 is formed on the surface of the semiconductor substrate 11 where the silicon nitride film 20 is not formed.

As shown in FIG. 7, the silicon nitride film 20, the first polysilicon film 19, and the silicon oxide film 18 are removed by the CDE (Chemical Dry Etching), for instance, and the surface of the N well 16 and the P well 17 where the field insulation film 24 is not formed is exposed.

As shown in FIG. 8, a gate oxide film 25 is formed on the entire surface, and on the gate oxide film 25 a polysilicon film 26 is formed. Then on the polysilicon film 26 a tungsten silicon (WSi) film 27 is formed by the sputtering, for instance. On the tungsten silicon film 27 a silicon oxide film 28 is formed, and then on the silicon oxide film 28 a silicon nitride film 29 is formed. And on the silicon nitride film 29 resists 30 are formed and patterned.

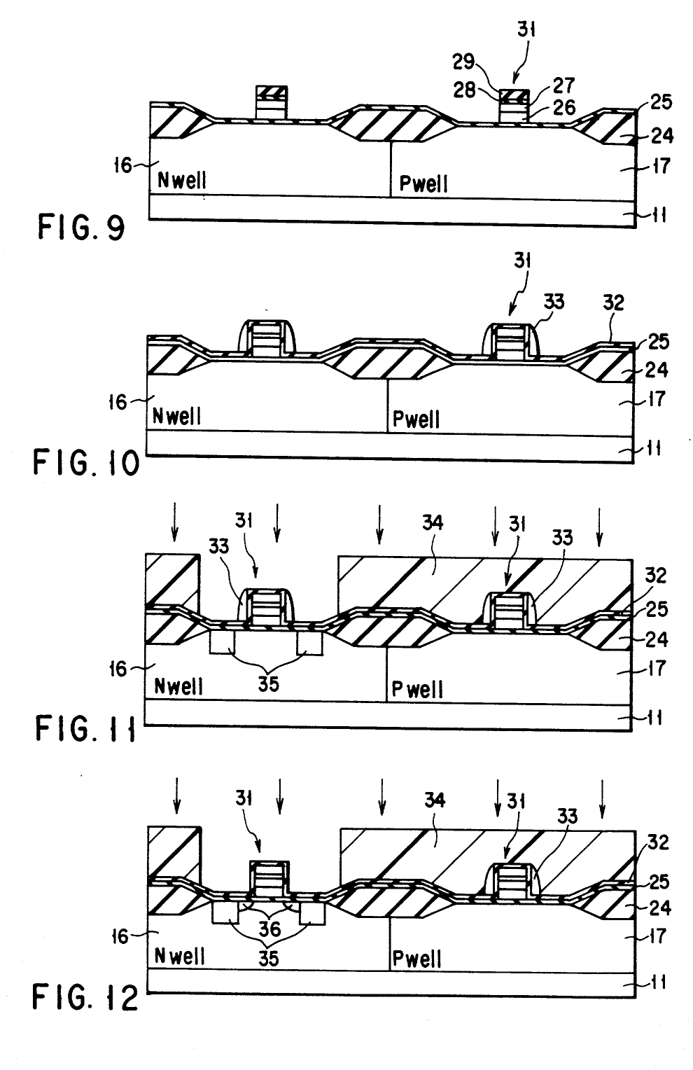

As shown in FIG. 9, with the patterned resists 30 as a mask, the silicon nitride film 29, the silicon oxide film 28, the tungsten silicon film 27 and the polysilicon film 26 are removed by the RIE, for instance. As a result, gate electrodes 31 of a P-channel transistor and an N-channel transistor are formed. Then the resists 30 are removed and the wet treatment is performed on the entire surface.

As shown in FIG. 10, a silicon oxide film 32 is formed on the entire surface, and on the silicon oxide film 32 a polysilicon film is formed. The polysilicon film is removed thereafter by the RIE, for example, and a gate sidewall 33 made from a polysilicon film is formed on the side of the gate electrodes 31.

As shown in FIG. 11, a resist 34 is formed on the entire surface and is patterned. With the patterned resist 34 as a mask, ions are implanted, and a P-type high density source drain region 35 is formed on the surface region of the N well 16. The condition of the ion implantation is that when boron fluoride (BF₂), for example, is used as an ion, the acceleration voltage be 45 keV and the dose be 3.0×10¹⁵ cm⁻².

As shown in FIG. 12, the gate sidewall 33 is removed by the CDE, for instance. Then ions are implanted, and a source drain region 36 the density of which is lower than that of the P-type source drain region 35 is formed on the surface region of the N well 16. The condition of the ion implantation is that when boron fluoride, for example, is used as an ion, the acceleration voltage be 35 keV and the dose be 1.0×10¹⁴ cm⁻². The resist 34 is removed thereafter.

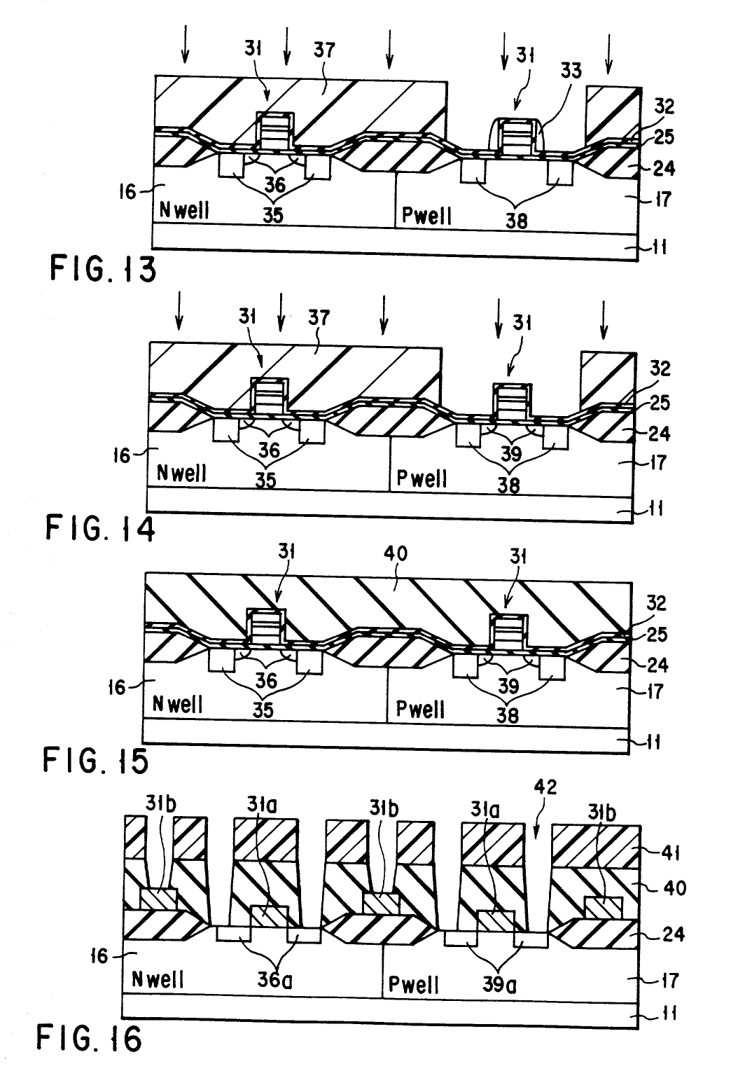

As shown in FIG. 13, a resist 37 is formed on the entire surface and patterned. With the patterned resist 37 as a mask, ions are implanted, and an N-type high density source drain region 38 is formed on the surface region of the P well 17. The condition of the ion implantation is that when arsenic (As), for example, is used as an ion, the acceleration voltage be 60 keV and the dose be 5.0×10¹⁵ cm⁻².

As shown in FIG. 14, the gate sidewall 33 is removed by the CDE, for instance. Then ions such as phosphorus and then arsenic are implanted. As a result, a source drain region 39 the density of which is lower than that of the N-type source drain region 38 is formed on the surface region of the P well 17. The condition of the ion implantation is that in the case of phosphorus the acceleration voltage be 40 keV and the dose be 4.0×10¹³ cm⁻², and in the case of arsenic the acceleration voltage be 60 keV and the dose be 2.0×10¹⁴ cm⁻². Then the resist 37 is removed and the entire surface is annealed.

As shown in FIG. 15, an interlayer insulation film 40 which is a CVDSiO₂ film containing phosphorus or boron is formed on the entire surface, and thereafter the interlayer insulation film 40 is flattened by the CMP, for example. The interlayer insulation film 40 is not limited to a CVDSiO₂ film containing phosphorus or boron, and may be aluminum or BPSG of PSG, and so on.

In the subsequent processes, the P-type high density source drain region 35 and the P-type low density source drain region 36 are called a P-type source drain region 36a, and the N-type high density source drain region 38 and the N-type low density source drain region 39 are called an N-type source drain region 39a. And the gate electrodes 31 are given the numeral 31a, and the passing gate electrodes which are formed on the field insulation film 24 at the same time when the gate electrodes 31 are formed are given the numeral 31b.

As shown in FIG. 16, a resist 41 is formed on the interlayer insulation film 40, and is patterned. With the patterned resist 41 as a mask, the interlayer insulation film 40 is etched by the RIE, for example. As a result, the surface of the source drain regions 36a, 39a and the passing gate electrodes 31b is exposed, and contact holes 42 are formed. Then the resist 41 is removed. It is possible to use different resists as a mask used when the contact holes 42 are formed on the field insulation film 24 and on the source drain diffusion regions 36a, 39a. Furthermore, it is possible to vary the shape, size, length, and so on of the contact holes 42, so long as the change will not harm the effects of the present invention.

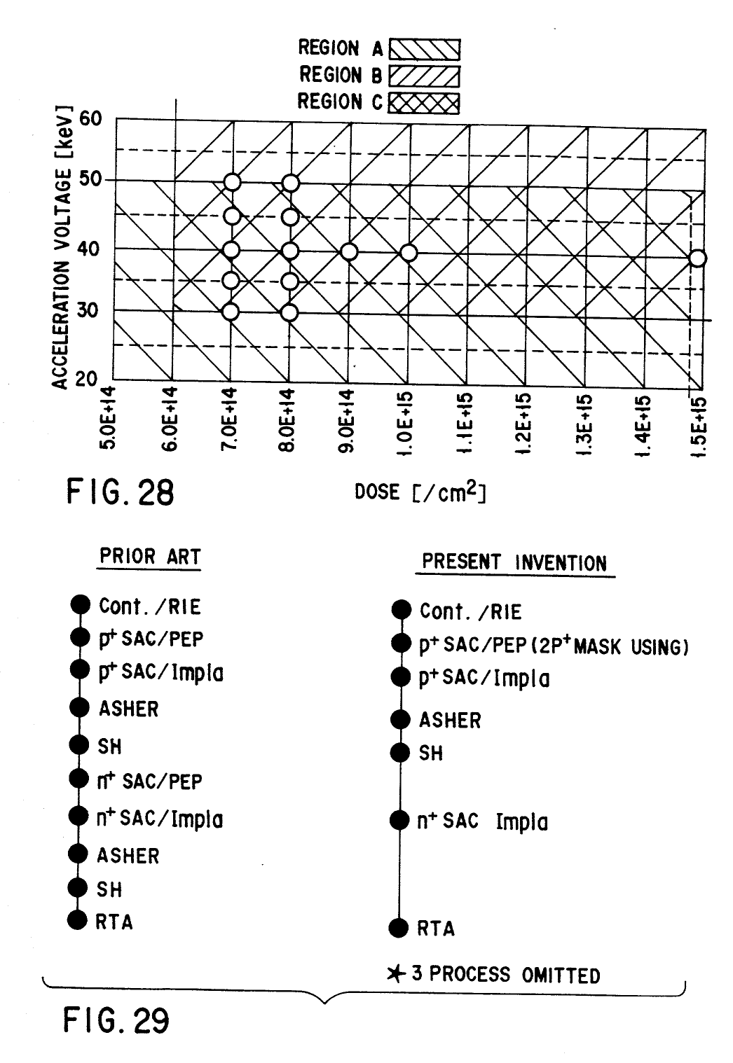

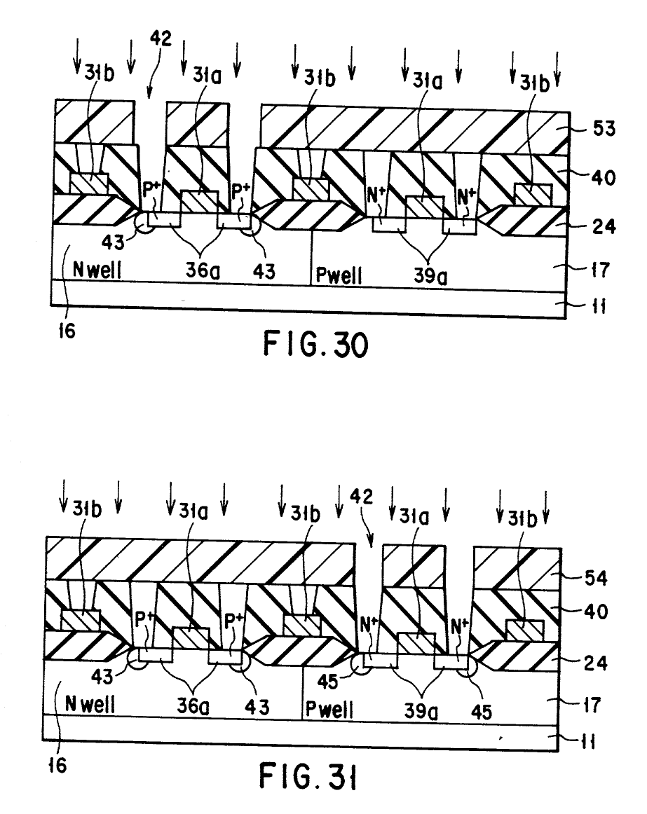

As shown in FIG. 17, ions are implanted from the contact holes 42 without the P well 17 being masked, and a P-type rediffusion region 43 adjacent to the source drain region 36a is formed on the surface of the N well 16 at the bottom of the contact holes 42. The condition of the ion implantation is that when boron fluoride, for example, is used as an ion, the acceleration voltage be 40 keV and the dose be 8.0×10¹⁴ cm⁻². Although ions are implanted in the P well 17, no P-type rediffusion region is formed because of the conditions described below (shown in FIG. 28).

As shown in FIG. 18, a resist 44 is formed on the interlayer insulation film 40, and is patterned. With the patterned resist 44 as a mask, ions are implanted from the contact holes 42, and thereby an N-type rediffusion region 45 adjacent to the source drain region 39a is formed on the surface of the P well 17 at the bottom of the contact holes 42. The condition of the ion implantation is that when phosphorus, for example, is used as an ion, the acceleration voltage be 60 keV and the dose be 3.0×10¹⁵ cm⁻². The resist 44 is removed thereafter.

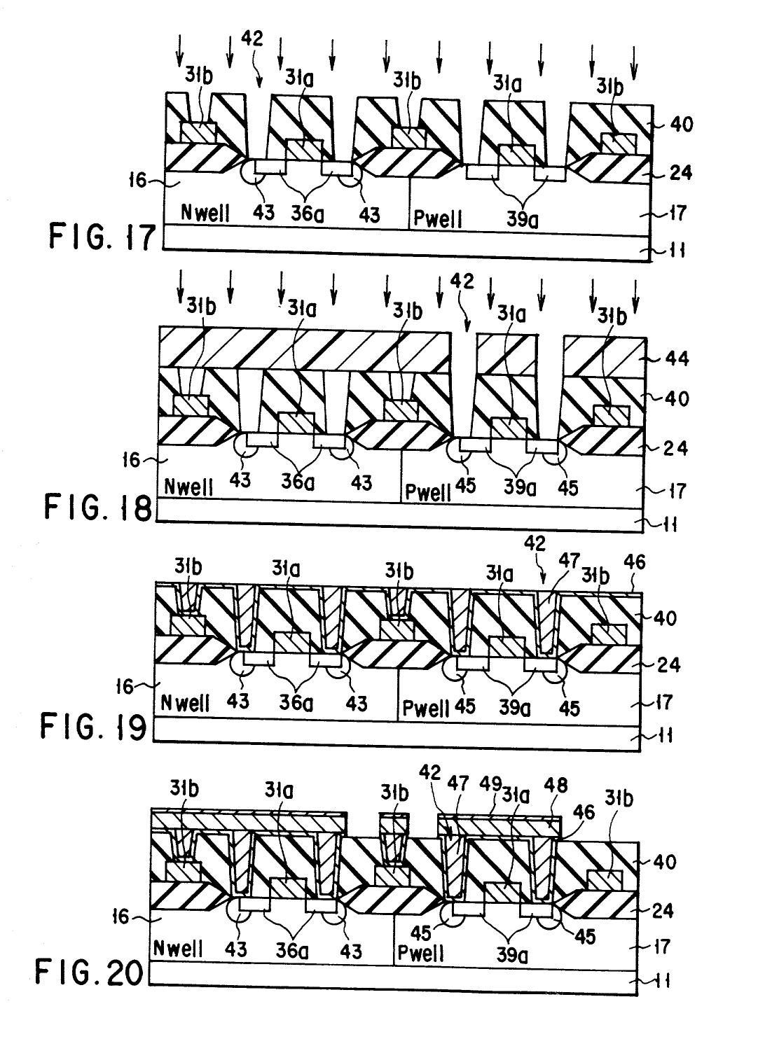

As shown in FIG. 19, a titanium nitride film 46 is formed on the entire surface by the sputtering, for instance. Then, a tungsten (W) film 47 is formed on the titanium nitride film 46 by the CVD (Chemical Vapor Deposition), for example, and the contact holes 42 are buried therein. The tungsten film 47 is flattened thereafter by the CDE, for example, and the surface of the titanium nitride film 46 is exposed.

As shown in FIG. 20, an aluminum film 48 is formed on the entire surface by the sputtering, for instance, and on the aluminum film 48 a titanium nitride film 49 is formed. Then on the titanium nitride film 49 a patterned resist (not shown) is formed, and with the resist as a mask, the titanium nitride films 46, 49 and the aluminum film 48 are removed by the RIE, for example, and thereby wiring is formed which is connected to the tungsten film 47 in the contact holes 42.

As shown in FIG. 21, a film such as a first TEOS (Tetra Ethyl Ortho Silicate) film 50 is formed on the entire surface, and the first TEOS film 50 is flattened by the CMP. Then on the first TEOS film 50 a second TEOS film 51 is formed.

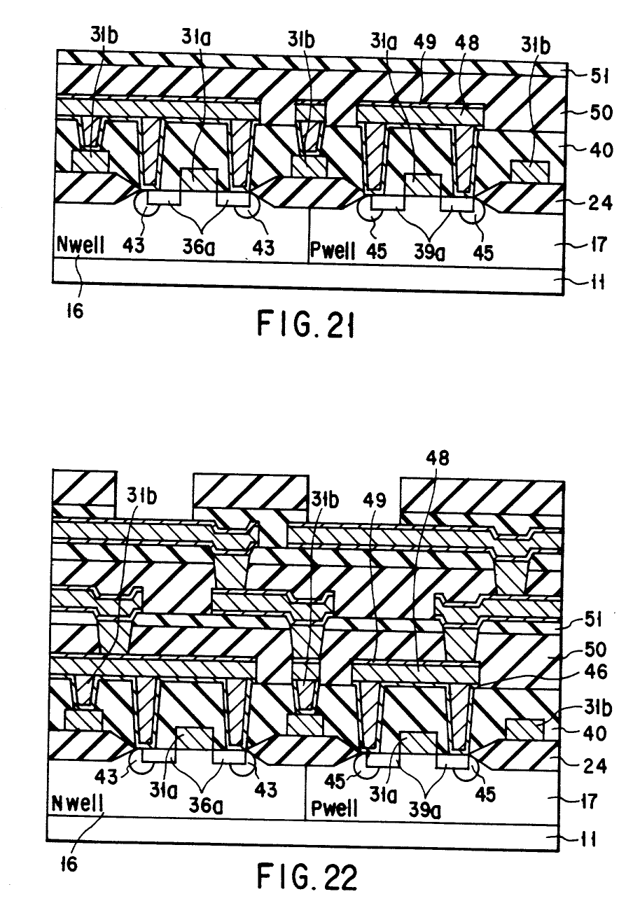

Finally, a via and wiring and so on are formed, and three-layer metal wiring is formed as shown in FIG. 22.

FIG. 28 shows the condition of the ion implantation when the rediffusion region 45 shown in FIG. 18 is formed. In FIG. 28, the transverse axis shows the dose, while the ordinate axis shows the acceleration voltage.

As shown in FIG. 28, the region A is where good contact cannot be obtained because the contact resistance is high. The region B is where there arises a junction leak because the dose for the ion implantation is high. And the region C is where the region A and the region B overlap, wherein the process margin is good. Accordingly, when the P-type and N-type rediffusion regions are formed with the process of forming a mask for one electrical conductivity being omitted, the region C shows the condition of the ion implantation when a rediffusion region is formed without a mask. That is, in the first embodiment, when the rediffusion region 43 is formed, it is desirable that the acceleration voltage be from 30 to 50 keV, and the dose be from 6.0×10¹⁴ to 1.5×10¹⁵ cm⁻² (region C), and the condition of 40 keV of the acceleration voltage and 8.0×10¹⁴ cm⁻² of the dose is best.

It is necessary that the dose when ions are implanted on the entire surface without a mask be smaller than the dose when ions are implanted on the entire surface with a mask. That is, in order not to affect the N-type rediffusion region 45 shown in FIG. 18, it is necessary that the dose of boron fluoride introduced when the P-type rediffusion region 43 is formed be smaller than the dose of phosphorus introduced when the N-type rediffusion region 45 is formed.

Accordingly, when the P-type and N-type rediffusion regions are formed with the process of forming a mask for one electrical conductivity omitted, if the rediffusion region 43 formed without a mask is formed with the ion implantation condition in the region C (Condition 1), and if the dose when ions are implanted on the entire surface without a mask is smaller than the dose when ions are implanted with a mask (Condition 2), it is possible to prevent the contact resistance from increasing or a leak current from occurring.

According to the first embodiment, owing to the Conditions 1 and 2, it is not necessary to form a mask on the P well 17 when the P-type rediffusion region 43 is formed on the N well 16.

As can be seen in the process flow shown in FIG. 29. Thus it is possible to omit three processes from the manufacturing process in prior art: the process of the application, exposure, and development of a resist (n⁺SAC/PEP), the process of ashing a resist (asher), and the removal process by the SH (SH); thus the manufacturing process becomes simpler.

Because masks need to be removed less often, less dust rises, and thereby the yield improves.

In the first embodiment, it is possible to change of the process between FIG. 17 and FIG. 18. In this case, it is possible to obtain the effects similar to the above-described effect.

[Second Example]

In a second embodiment, unlike in the first embodiment, a P-type rediffusion region is formed after an N-type rediffusion region is formed. The same processes in the second embodiment as in the first embodiment are not explained, and only different processes are described below.

First, as shown in FIG. 1 to FIG. 16, as in the first embodiment, contact holes 42 are formed. Then a resist 41 is removed.

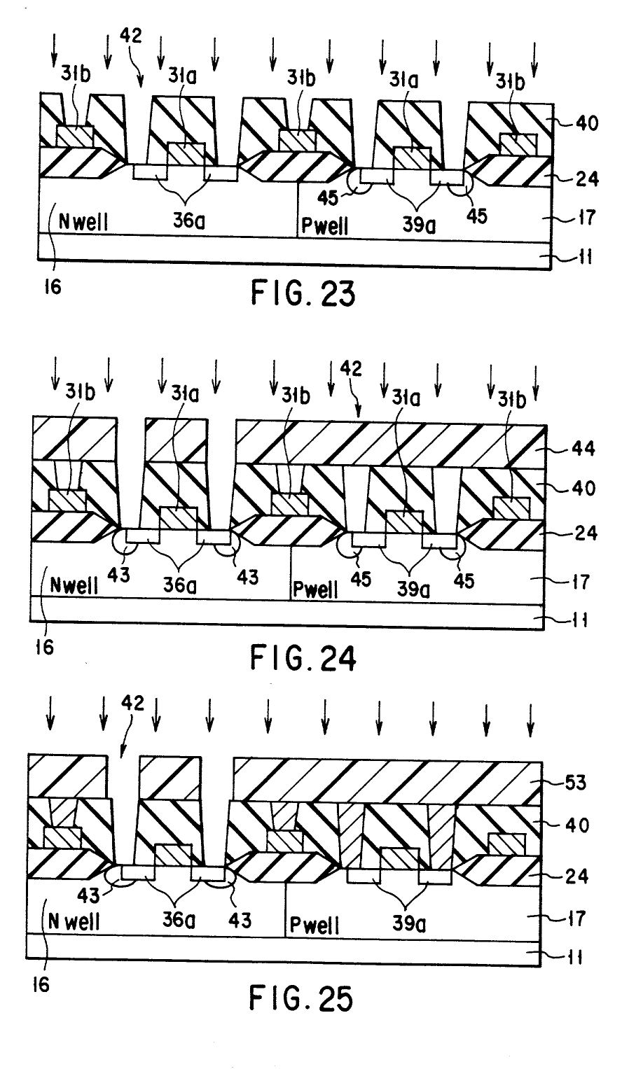

Then, as shown in FIG. 23, ions are implanted from the contact holes 42 without an N well 16 being masked, an N-type rediffusion region 45 adjacent to a source drain region 39a is formed on the surface of a P well 17 at the bottom of the contact holes 42. The condition of the ion implantation is that when phosphorus, for example, is used as an ion, the acceleration voltage be 40 keV and the dose be 8.0×10¹⁴ cm⁻².

As shown in FIG. 24, a resist 44 is formed on an interlayer insulation film 40 and is patterned. With the patterned resist 44 as a mask, ions are implanted from the contact holes 42, and thereby a P-type rediffusion region 43 adjacent to a source drain region 36a is formed on the surface of the N well 16 at the bottom of the contact holes 42. The condition of the ion implantation is that when boron fluoride, for example, is used as an ion, the acceleration voltage be 60 keV and the dose be 3.0×10¹⁵ cm⁻². The resist 44 is removed thereafter. The P-type rediffusion region 43 and the N-type rediffusion region 45 are formed according to the above-described Conditions 1 and 2.

Thereafter, as in the first embodiment, as shown in FIG. 19 to FIG. 22, a semiconductor device having a laminated structure is formed.

In the second embodiment, it is possible to obtain the effects similar to those in the first embodiment if different kinds of ions are implanted when the rediffusion regions are formed.

[Third Example]

In a third embodiment, unlike in the first embodiment, a P-type rediffusion region is formed with a mask, while an N-type rediffusion region is formed without a mask. The same processes in the third embodiment as in the first embodiment are not explained, and only different processes are described below.

First, as shown in FIG. 1 to FIG. 16, as in the first embodiment, contact holes 42 are formed. Then a resist 41 is removed.

Then, as shown in FIG. 25, a resist 53 is formed on an interlayer insulation film 40 and is patterned. Then ions are implanted from the contact holes 42, and a P-type rediffusion region 43 adjacent to a source drain region 36a is formed on the surface of an N well 16 at the bottom of the contact holes 42. The condition of the ion implantation is that when boron fluoride, for example, is used as an ion, the acceleration voltage be 60 keV and the dose be 3.0×10¹⁵ cm⁻². The resist 53 is removed thereafter.

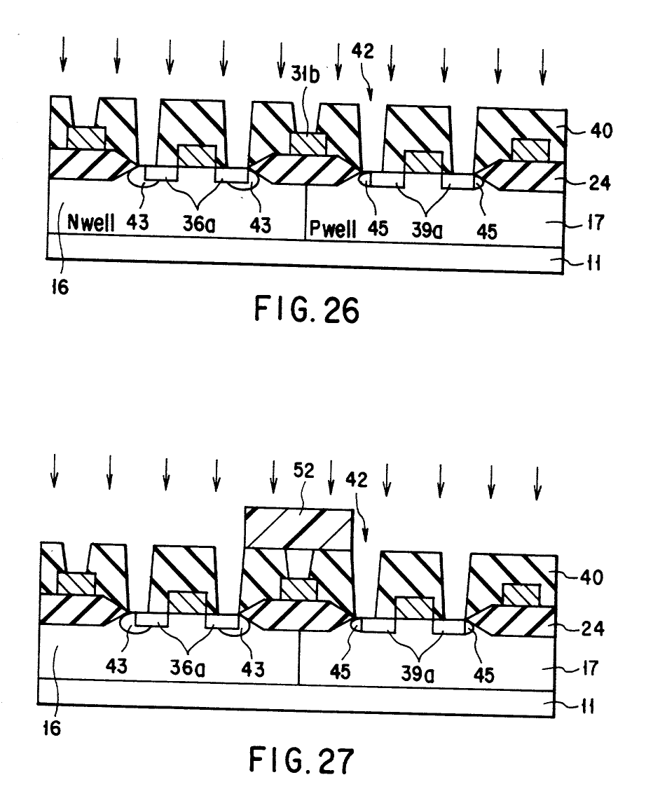

As shown in FIG. 26, ions are implanted from the contact holes 42 without the N well 16 being masked, and an N-type rediffusion region 45 adjacent to a source drain region 39a is formed on the surface of the P well 17 at the bottom of the contact holes 42. The condition of the ion implantation is that when phosphorus, for example, is used as an ion, the acceleration voltage be 40 keV and the dose be 8.0×10¹⁴ cm⁻². Then the RTA (Rapid Thermal Annealing) is carried out. The P-type rediffusion region 43 and the N-type rediffusion region 45 are formed according to the above-described Conditions 1 and 2. Although ions are implanted in passing gate electrodes 31b, the performance of elements does not deteriorate so long as ions are implanted according to the above Conditions 1 and 2.

Thereafter, as in the first embodiment, as shown in FIG. 19 to FIG. 22, a semiconductor device having a laminated structure is formed.

In the third embodiment, it is possible to obtain the effects similar to those in the first embodiment. In addition, it is possible to form the N-type rediffusion region 45 without the passing gate electrodes 31b being masked after the P-type rediffusion region 43 is formed. Thus it is possible to omit the process of forming a mask of the passing gate electrodes 31b, and thereby the manufacturing process becomes simpler.

As shown in FIG. 27, it is possible to implant ions for the purpose of forming the N-type rediffusion region 45 after forming the resist 52 on the passing gate electrodes 31b. In this case, too, it is possible to obtain the effects similar to those in the first embodiment.

In the first to third embodiments, the number of the masking processes in forming the P-type rediffusion region 43 or the N-type rediffusion region 45 was reduced by following Conditions 1 and 2; it is also possible to reduce the number of the masking processes in forming the source drain regions by forming the source drain regions according to Conditions 1 and 2, for example.

The kind of ions used in forming the rediffusion regions 43, 45 is not limited to P or BF₂. If different kinds of ions are used, the value of the region C varies to such an extent that the rise in the contact resistance or the occurrence of a leak current may be prevented.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device comprising the steps of;
forming a first electrically conductive first well region and a second electrically conductive second well region in the surface region of a semiconductor substrate, a first transistor and a second transistor having a second electrically conductive first diffusion layer and a first electrically conductive second diffusion layer in the first and second well regions respectively, and an insulation film having contact holes which expose at least said first and second diffusion layers of the first and second transistors; and having
a process of implantation first ions on the entire surface of said semiconductor substrate from said contact holes, and thereby forming a second electrically conductive first rediffusion region adjacent to said first diffusion layer in said first well region,
a process of forming a mask covering said first well region of said semiconductor substrate; and
a process of implantation second ions in said second well region from said contact holes using said mask, and thereby forming the first electrically conductive second rediffusion region adjacent to said second diffusion layer in the second well region;
wherein the dose in implantation the first ions in the process of forming said first rediffusion region is smaller than the dose in implantation the second ions in the process of forming said second rediffusion layer.

2. The method according to claim 1, wherein the condition of implantation the first ions in forming said first rediffusion region is that the acceleration voltage be from 30 to 50 keV and the dose be from 6.0×10¹⁴ to 1.5×10¹⁵ cm⁻² while the condition of implantation the second ions in forming said second rediffusion region is that the acceleration voltage be 60 keV and the dose be 3.0×10¹⁵ cm⁻².

3. The method according to claim 1, wherein the condition of implantation the first ions in forming said first rediffusion region is that the acceleration voltage be 40 keV and the dose be 8.0×10¹⁴ cm⁻², while the condition of implantation the second ions in forming said second rediffusion region is that the acceleration voltage be 60 keV and the dose be 3.0×10¹⁵ cm⁻².

4. A method of manufacturing a semiconductor device comprising the steps of;
forming a first electrically conductive first well region and a second electrically conductive second well region in the surface region of a semiconductor substrate, a first transistor and a second transistor having a second electrically conductive first diffusion layer and a first electrically conductive second diffusion layer in the first and second well regions respectively, and an insulation film having contact holes which expose at least said first and second diffusion layers of the first and second transistors; and having
a process of forming a mask covering said second well region of said semiconductor substrate,
a process of implantation first ions in said first well region from said contact holes using said mask, and thereby forming the second electrically conductive first rediffusion region adjacent to said first diffusion layer in said first well region,
a process of removing said mask; and
a process of implantation second ions on the entire surface of said semiconductor substrate from said contact holes, and thereby forming the first electrically conductive second rediffusion region adjacent to said second diffusion layer in said second well region;
wherein the dose in implantation the second ions in the process of forming said second rediffusion layer is smaller than the dose in implantation the first ions in the process of forming said first rediffusion region.

5. The method according to claim 4, wherein the condition of implantation the second ions in forming said second rediffusion region is that the acceleration voltage be from 30 to 50 keV and the dose be from 6.0×10¹⁴ to 1.5×10¹⁵ cm⁻², while the condition of implantation the first ions in forming said first rediffusion region is that the acceleration voltage be 60 keV and the dose be 3.0×10¹⁵ cm⁻².

6. The method according to claim 4, wherein the condition of implantation the second ions in forming said second rediffusion region is that the acceleration voltage be 40 keV and the dose be 8.0×10¹⁴ cm⁻², while the condition of implantation the first ions in forming said first rediffusion region is that the acceleration voltage be 60 keV and the dose be 3.0×10¹⁵ cm⁻².
